(19) United States
(12) Patent Application Publication
(10) Pub. No.: US 2012/0168935 A1
(43) Pub. Date: Jul. 5, 2012

(54) INTEGRATED CIRCUIT DEVICE AND METHOD FOR PREPARING THE SAME

(75) Inventor: Tsai Yu Huang, Zhubei City (TW)

(73) Assignee: NANYA TECHNOLOGY CORP., Kueishan (TW)

(21) Appl. No.: 12/983,358

(22) Filed: Jan. 3, 2011

(51) Int. Cl. H01L 23/48; H01L 21/30

(52) U.S. Cl. 257/737; 257/774; 438/455; 257/E21.211; 257/E23.011

(57) ABSTRACT

An integrated circuit device includes a bottom wafer having a first annular dielectric block, at least one stacking wafer having a second annular dielectric block positioned on the bottom wafer, and a conductive via penetrating through the stacking wafer and into the bottom wafer in a substantially linear manner. In one embodiment of the present invention, the bottom wafer and the stacking wafer are bonded by an intervening adhesive layer, no bump pad is positioned between the bottom wafer and the stacking wafer, and the conductive via is positioned within the first annular dielectric block and the second annular dielectric block.

### 1. TECHNICAL FIELD

The present invention relates to an integrated circuit device having stacking wafers with through silicon vias and a method for preparing the same. More particularly, the present invention relates to an integrated circuit device of stacked wafers and method for preparing the same by bonding wafers before the formation of the through silicon via without forming a bump pad between the bonded wafers or using solder.

### 2. BACKGROUND

Packaging technology for integrated circuit structures has continuously developed to meet the demand for miniaturization and mounting reliability. Recently, as the miniaturization and high functionality of electric and electronic products are required, various techniques have been disclosed in the art.

By using a stack of at least two chips, i.e., the so-called 3D package, in the case of a memory device, it is possible to produce a product having a memory capacity which is twice as large as that obtainable through semiconductor integration processes. Also, a stack package provides advantages not only of an increase in memory capacity but also in regards to mounting density and mounting area utilization efficiency. Due to such advantages, research and development of stack package technology has accelerated.

As an example, a stack package with a through-silicon via (TSV) has been disclosed in the art. The stack package using a TSV has a structure in which the TSV is disposed in a chip so that chips are physically and electrically connected with each other through the TSV. Generally, a TSV is formed by etching a vertical via through a substrate and filling the via with a conductive material, such as copper. To increase the transmission speed and for high-density fabrication, the thickness of a semiconductor wafer comprising multiple integrated circuit structures each having the TSV should be reduced.

U.S. Pat. No. 7,683,459 discloses a hybrid bonding method for through silicon via based wafer stacking, in which patterned adhesive layers are provided to join together adjacent wafers in the stack, while solder bonding is used to electrically connect the lower end of the via in the upper wafer to the bump pad on the upper end of the via in the lower wafer. However, the formation of the bump pad on the upper end of the via requires seeding, electroplating, photolithography and etching processes; therefore, the formation of the bump pad on the upper end of the via is very complicated and expensive.

### SUMMARY

An aspect of the present invention is to provide an integrated circuit device of stacked wafers and method for preparing the same by bonding wafers prior to the formation of the through silicon via such that no bump pad is positioned between the stacking wafer and the bottom wafer; therefore, the issues of complicated processing and high cost can be resolved.

One aspect of the present invention discloses an integrated circuit device comprising a bottom wafer having a first annular dielectric block, at least one stacking wafer having a second annular dielectric block positioned on the bottom wafer, and a conductive via penetrating through the stacking wafer and into the bottom wafer in a substantially linear manner. In one embodiment of the present invention, the bottom wafer and the stacking wafer are bonded by an intervening adhesive layer, no bump pad is positioned between the bottom wafer and the stacking wafer, and the conductive via is positioned within the first annular dielectric block and the second annular dielectric block.

Another aspect of the present invention discloses a method for preparing an integrated circuit device comprising the steps of forming a bottom wafer having a first annular dielectric block, forming at least one stacking wafer having a second annular dielectric block, bonding the at least one stacking wafer to the bottom wafer by an intervening adhesive layer without forming a bump pad between the bottom wafer and the stacking wafer, and forming a conductive via penetrating through the stacking wafer and into the bottom wafer in a substantially linear manner, wherein the conductive via is formed within the first annular dielectric block and the second annular dielectric block.

Compared to the technique disclosed in U.S. Pat. No. 7,683,459 forming one bump pad for each wafer, the embodiment of the present invention forms the integrated circuit device by bonding wafers prior to the formation of the through silicon via that penetrates through the stacking wafer and not through the backside dielectric layer of the bottom wafer. Consequently, the embodiment of the present invention does not need to form the bump pad between the stacking wafer and the bottom wafer; therefore, the issues of complicated processing and high cost can be resolved.

In addition, the conductive via is formed within the first annular dielectric block of the bottom wafer and the second annular dielectric block of the stacking wafer, such that the second annular dielectric block electrically isolates the conductive via from other elements in the stacking wafer and the first annular dielectric block electrically isolates the conductive via from other elements in the bottom wafer.

The foregoing has outlined rather broadly the features and technical advantages of the present invention in order that the detailed description of the invention that follows may be better understood. Additional features and advantages of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes as those of the present invention. It should also be realized by those skilled in the art that such equivalent constructions do not depart from the spirit and scope of the invention as set forth in the appended claims.

### BRIEF DESCRIPTION OF THE DRAWINGS

The accompanying drawings, which are incorporated in and constitute a part of this specification, illustrate embodiments of the disclosure and, together with the description, serve to explain the principles of the invention.

FIG. 1 is a cross-sectional view of a silicon wafer in accordance with one embodiment of the present invention;

FIG. 2 and FIG. 3 are close-up top views of the silicon wafer in FIG. 1 in accordance with one embodiment of the present invention;

FIG. 4 is a cross-sectional view of the silicon wafer in accordance with one embodiment of the present invention;

FIG. 5 and FIG. 6 are close-up top views of the silicon wafer in FIG. 4 in accordance with one embodiment of the present invention;

FIG. 7 and FIG. 8 are cross-sectional views of the silicon wafer in accordance with one embodiment of the present invention;

FIG. 9 and FIG. 10 are cross-sectional views of the silicon wafer in accordance with one embodiment of the present invention;

FIG. 11 and FIG. 12 are cross-sectional views of the silicon wafer in accordance with one embodiment of the present invention;

FIG. 13 and FIG. 14 are cross-sectional views of a bottom wafer in accordance with one embodiment of the present invention;

FIG. 15 is a cross-sectional view of a stacking wafer in accordance with one embodiment of the present invention;

FIG. 16 is a cross-sectional view of the stacking wafer adhered to the bottom wafer in accordance with one embodiment of the present invention;

FIG. 17 is a cross-sectional view showing a via hole penetrating through the stacking wafer and into the bottom wafer in accordance with one embodiment of the present invention;

FIG. 18 is a cross-sectional view showing a conductive via formed in the via hole in accordance with one embodiment of the present invention;

FIG. 19 and FIG. 20 are cross-sectional views showing the integrated circuit device in accordance with one embodiment of the present invention; and

FIG. 21 and FIG. 22 are cross-sectional views showing an integrated circuit device in accordance with one embodiment of the present invention.

### DETAILED DESCRIPTION

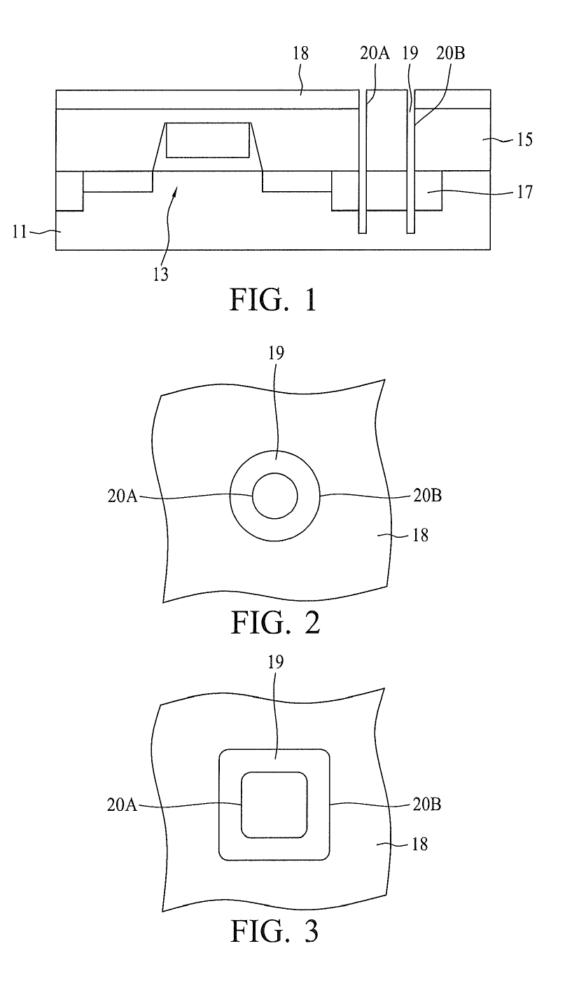

FIG. 1 to FIG. 20 are schematic diagrams showing a method for forming an integrated circuit device 100 in accordance with one embodiment of the present invention. FIG. 1 is a cross-sectional view of a silicon wafer 11 and FIG. 2 and FIG. 3 are close-up top views of the silicon wafer 11 in FIG. 1 in accordance with one embodiment of the present invention. In one embodiment of the present invention, fabrication processes are performed to form an active element 13 such as a transistor in the silicon wafer 11, with a dielectric layer 15 covering the active element 13 and a shallow trench isolation (STI) 17 next to the active element 13 in the silicon wafer 11. Subsequently, photolithographic process is performed to form a mask layer 18, and an etching process is then performed to form an annular depression 19 in the shallow trench isolation 17.

In one embodiment of the present invention, the annular depression 19 penetrates through the shallow trench isolation 17. In one embodiment of the present invention, the annular depression 19 has an inner edge 20A and an outer edge 20B, and the shapes of the inner edge 20A and the outer edge 20A are circular, as shown in FIG. 2. In one embodiment of the present invention, the shapes of the inner edge 20A and the outer edge 20A are rectangular with rounded corners, as shown in FIG. 3.

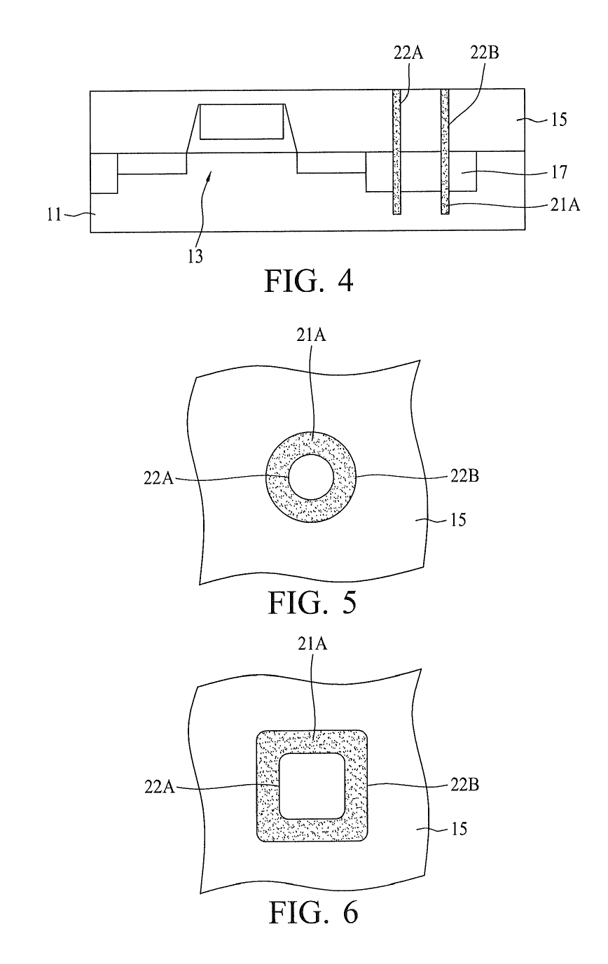

FIG. 4 is a cross-sectional view of the silicon wafer 11, and FIG. 5 and FIG. 6 are close-up top views of the silicon wafer 11 in FIG. 4 in accordance with one embodiment of the present invention. In one embodiment of the present invention, the mask layer 18 is stripped, and the annular depression 19 is filled with dielectric material by deposition process and CMP process to form an annular dielectric block 21A, as shown in FIG. 4 and FIG. 5. In one embodiment of the present invention, the annular dielectric block 21A has an inner sidewall 22A and an outer sidewall 22B. In one embodiment of the present invention, the shapes of the inner sidewall 22A and the outer sidewall 22B can be circular as shown in FIG. 5 or rectangular with rounded corners as shown in FIG. 6.

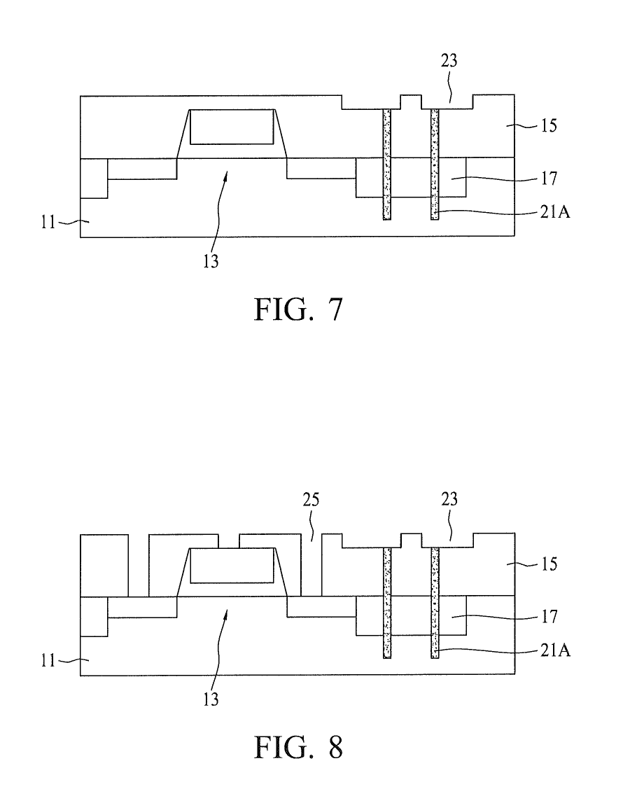

FIG. 7 and FIG. 8 are cross-sectional views of the silicon wafer 11 in accordance with one embodiment of the present invention. Referring to FIG. 7, in one embodiment of the present invention, photolithographic and etching processes are performed to remove a portion of the annular dielectric block 21A and the dielectric layer 15 to form at least one concavity 23. Subsequently, photolithographic and etching processes are performed to remove a portion of the dielectric layer 15 on the active element 13 to form at least one contact hole 25, which exposes at least one terminal of the active element 13, as shown in FIG. 8.

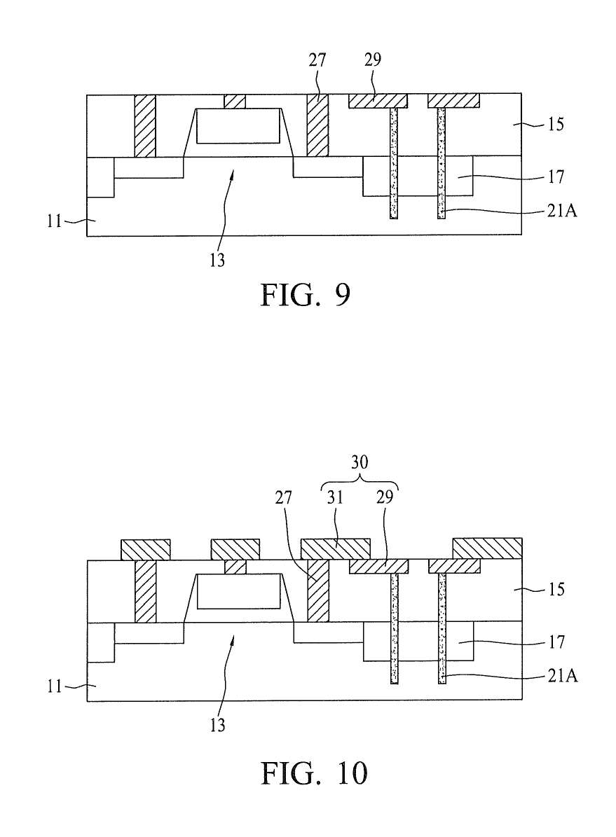

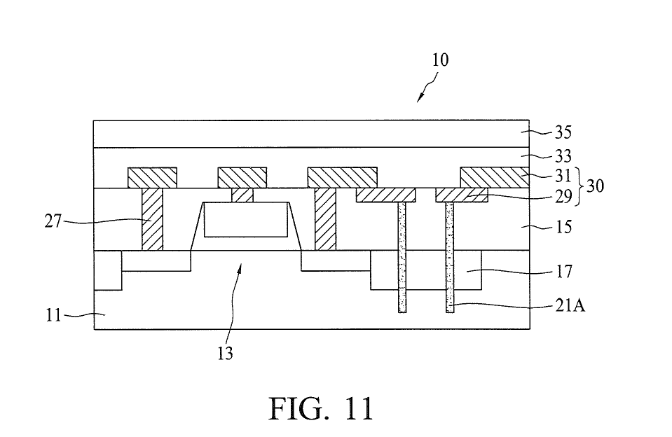

FIG. 9 and FIG. 10 are cross-sectional views of the silicon wafer 11 in accordance with one embodiment of the present invention. Referring to FIG. 9, in one embodiment of the present invention, a contact plug 27 is formed in the contact hole 25 and an interconnect 29 is formed in the concavity 23 with the same conductive material as that used by the deposition process and CMP process, such as tungsten. Subsequently, a conductive layer 31 is formed by deposition and etching process to electrically connect the interconnect 29 to the active element 13 through the contact plug 27, as shown in FIG. 10. In one embodiment of the present invention, the interconnect 29 and the conductive layer 31 form a connecting structure 30.

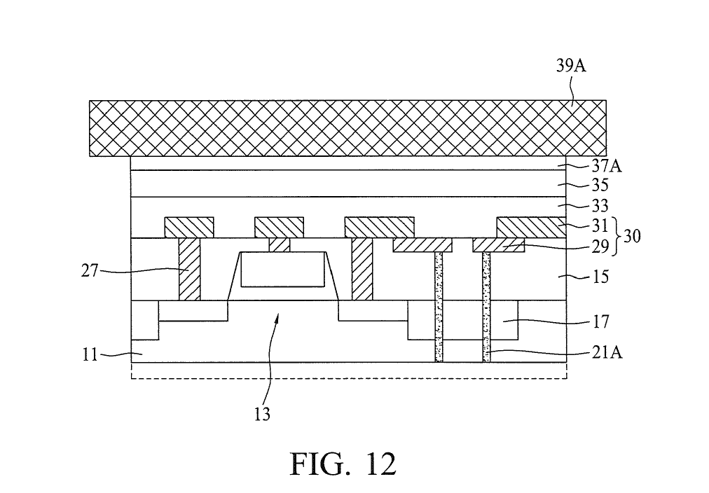

FIG. 11 and FIG. 12 are cross-sectional views of the silicon wafer 11 in accordance with one embodiment of the present invention. In one embodiment of the present invention, a dielectric layer 33 is formed by deposition process to cover the conductive layer 31 and a passivation layer 35 is then formed by deposition process to cover the dielectric layer 33. Subsequently, a carrier 39A is adhered to the top side of the wafer 10 via an adhesive 37A, and a thinning process such as the backside grinding process or CMP process is then performed to remove a portion of the wafer 10 from the bottom side of the wafer 10, as shown in FIG. 12. In one embodiment of the present invention, the thinning process is performed to remove a portion of the wafer 10 from the bottom side of the wafer 10 such that the bottom end of the annular dielectric block 21A is exposed.

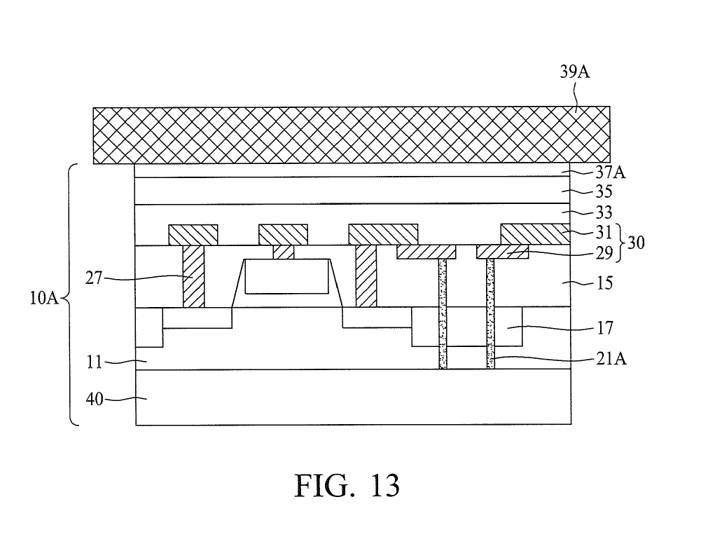

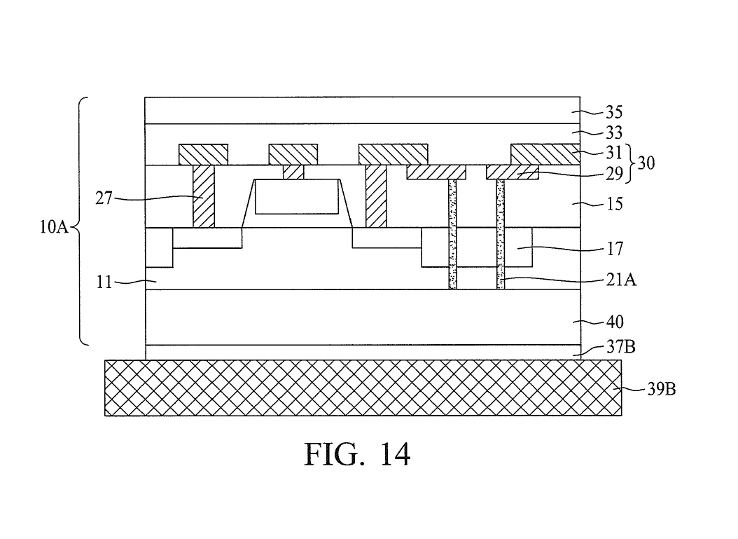

FIG. 13 and FIG. 14 are cross-sectional views of a bottom wafer 10A in accordance with one embodiment of the present invention. In one embodiment of the present invention, a backside dielectric layer 40 is deposited on the bottom side of the wafer 10A to form the bottom wafer 10A, and the backside dielectric layer 40 serves as an etching stop layer for the subsequent etching process to form the via hole. Subsequently, the carrier 39A and the adhesive 37A are removed, and another carrier 39B is adhered to the backside of the wafer 10A via an adhesive 37B, as shown in FIG. 14.

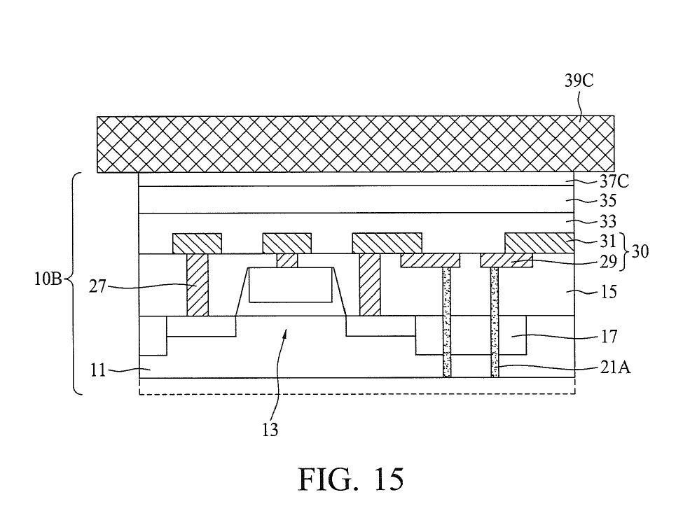

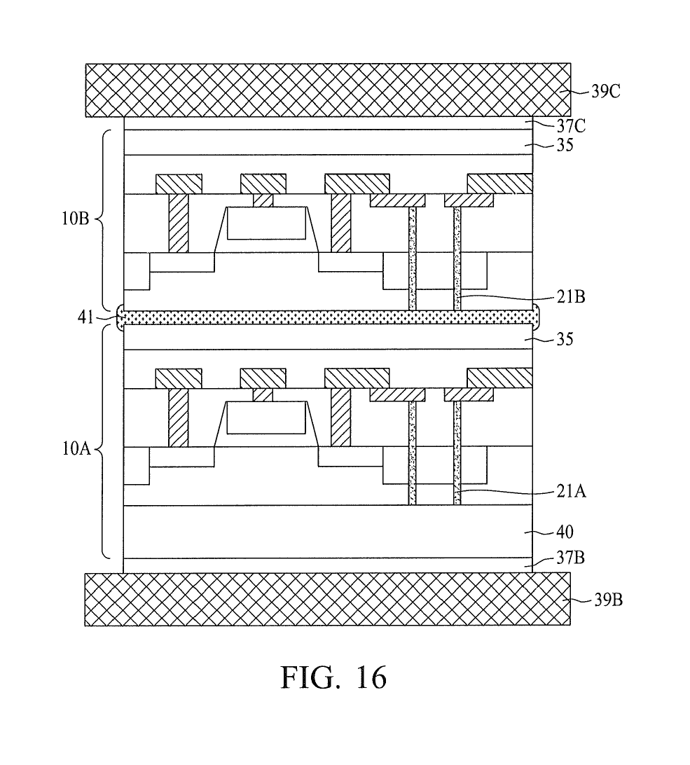

FIG. 15 is a cross-sectional view of a stacking wafer 10B in accordance with one embodiment of the present invention. In one embodiment of the present invention, the fabrication processes shown in FIG. 1 to FIG. 11 are performed again on another wafer 11 to form the stacking wafer 10B having an annular dielectric block 21B. Subsequently, a carrier 39C is adhered to the top side of the stacking wafer 10B via an adhesive 37C, and a thinning process such as the backside grinding process or CMP process is then performed to remove a portion of the stacking wafer 10B from the bottom side of the stacking wafer 10B, as shown in FIG. 15. In one embodiment of the present invention, the thinning process is performed to remove a portion of the stacking wafer 10B from the bottom side of the stacking wafer 10B such that the bottom end of the annular dielectric block 21B is exposed.

FIG. 16 is a cross-sectional view of the stacking wafer 10B adhered to the bottom wafer 10A in accordance with one embodiment of the present invention. In one embodiment of the present invention, the stacking wafer 10B is bonded to the bottom wafer 10A by an intervening adhesive layer 41 without forming a bump pad between the bottom wafer 10A and the stacking wafer 10B. In one embodiment of the present invention, the intervening adhesive layer 41 is the only layer between the bottom wafer 10A and the stacking wafer 10B, i.e., the stacking wafer 10B is bonded to the bottom wafer 10A without using solder. In one embodiment of the present invention, the carrier 39C and the adhesive 37C are removed from the top side of the stacking wafer 10B, and another stacking wafer 10B can be adhered to the top side of the stacking wafer 10B by the same technique, and so on, i.e., one or more stacking wafers 10B can be adhered to the bottom wafer 10A.

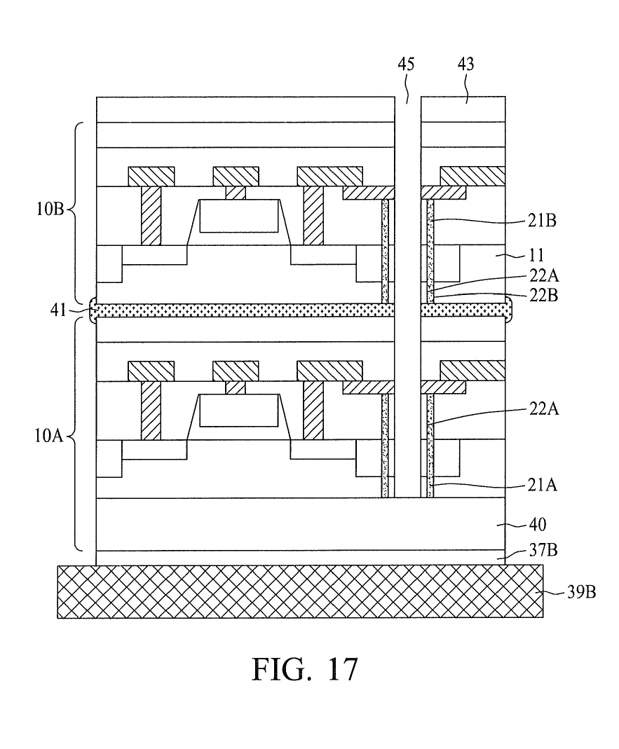

FIG. 17 is a cross-sectional view showing a via hole 45 penetrating through the stacking wafer 10B and into the bottom wafer 10A in accordance with one embodiment of the present invention. In one embodiment of the present invention, the carrier 39C and the adhesive 37C are removed from the top side of the stacking wafer 10B, and a photolithographic process is then performed to form a mask layer 43 on the stacking wafer 10B. Subsequently, a dry etching process using fluorine-containing etching gas is then performed by using the backside dielectric layer 40 as an etching stop layer to form at least one via hole 45 penetrating through the stacking wafer 10B and into the bottom wafer 10A in a substantially linear manner. In one embodiment of the present invention, the at least one via hole 45 does not penetrate through the backside dielectric layer 40 of the bottom wafer 10A. In one embodiment of the present invention, the at least one via hole 45 is formed within the annular dielectric block 21A and the annular dielectric block 21B. In one embodiment of the present invention, the via hole 45 does not expose the inner sidewall 22A of the annular dielectric block 21A.

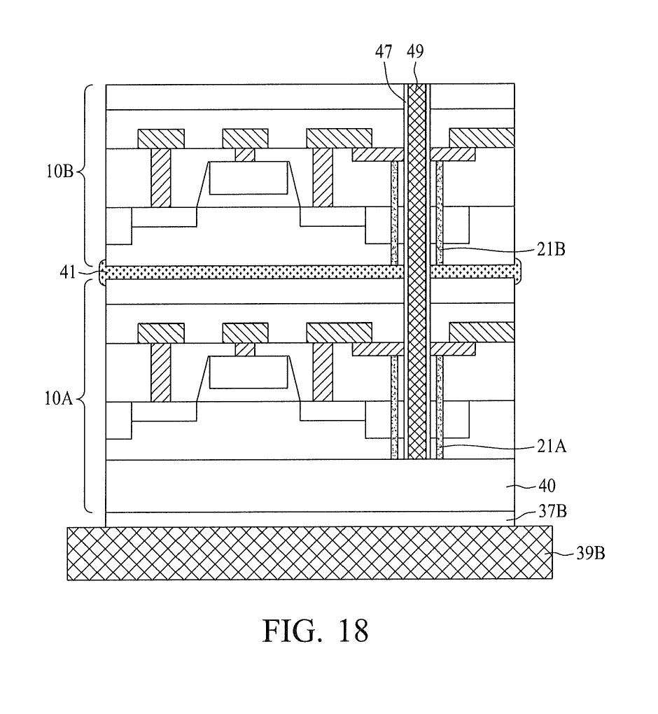

FIG. 18 is a cross-sectional view showing a conductive via 49 formed in the via hole 45 in accordance with one embodiment of the present invention. In one embodiment of the present invention, the mask layer 43 is stripped, and a barrier layer and seed layer 47 is formed in the via hole 45 by physical vapor deposition. Subsequently, an electroplating process is then performed to form the conductive via (TSV) 49 by filling the via hole 43 with conductive material such as copper. In one embodiment of the present invention, the conductive via 47 penetrates through the stacking wafer 10B, and into the bottom wafer 10A. In particular, the conductive via 47 does not penetrate through the backside dielectric layer 40 of the bottom wafer 10A. In one embodiment of the present invention, the conductive via 47 is formed within the annular dielectric block 21A and the annular dielectric block 21B, such that the annular dielectric block 21B electrically isolates the conductive via 47 from other elements in the stacking wafer 10B and the annular dielectric block 21A electrically isolates the conductive via 47 from other elements in the bottom wafer 10A.

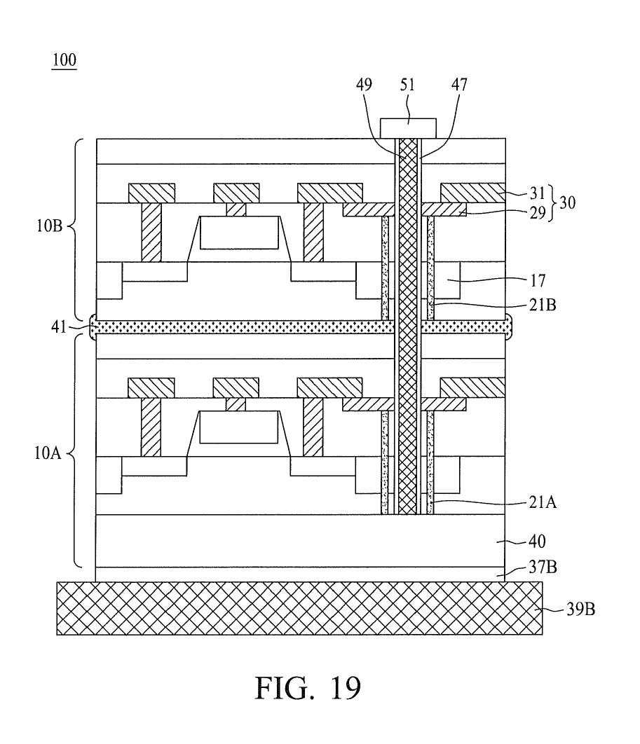

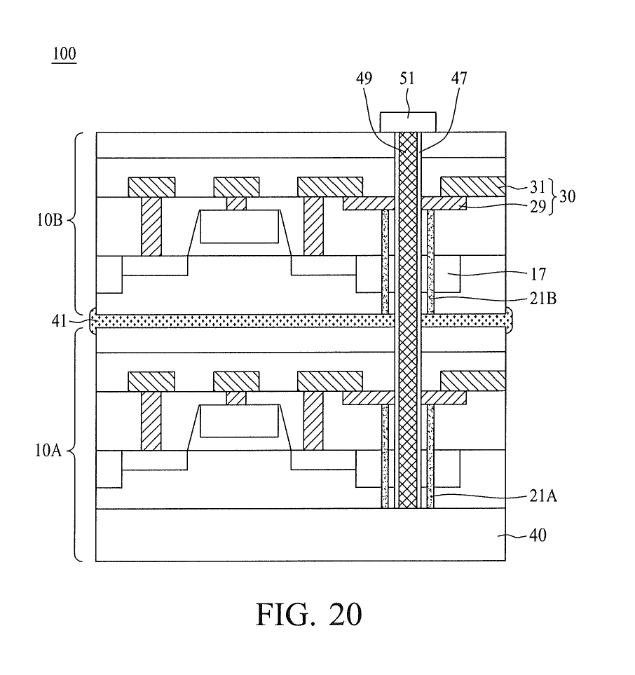

FIG. 19 and FIG. 20 are cross-sectional views showing the integrated circuit device 100 in accordance with one embodiment of the present invention. In one embodiment of the present invention, a bump pad 51 is formed on the stacking wafer 108 to complete the integrated circuit device 100. In one embodiment of the present invention, the conductive via 49 is positioned in the shallow trench isolation 17 and connected to the bump pad 49, and the carrier 39B and the adhesive 37B are removed from the back side of the bottom wafer 10A, as shown in FIG. 20. In one embodiment of the present invention, the conductive via 49 is electrically connected to the interconnect 29 of the connecting structure 30, and the conductive layer 31 of the connecting structure 30 electrically connects the active element 13 to the interconnect 29; therefore, the active element 13 is electrically connected to the conductive via 49.

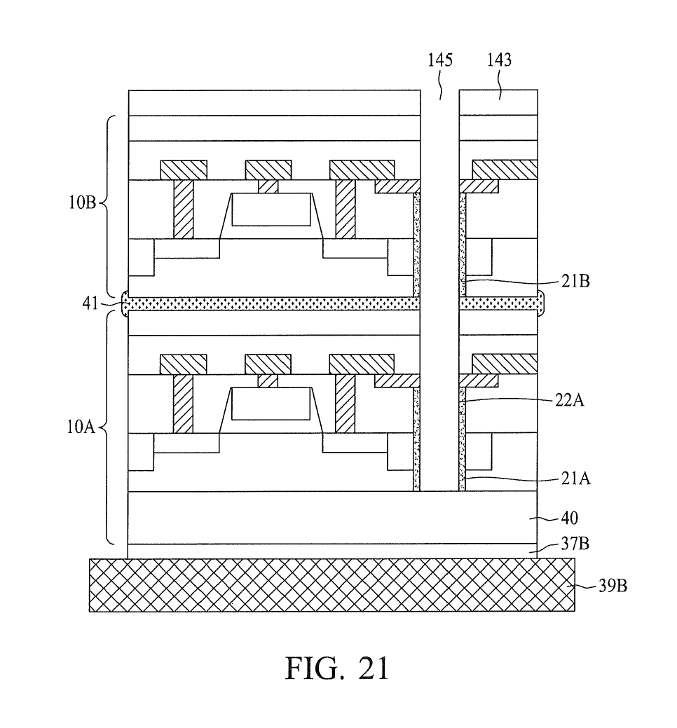

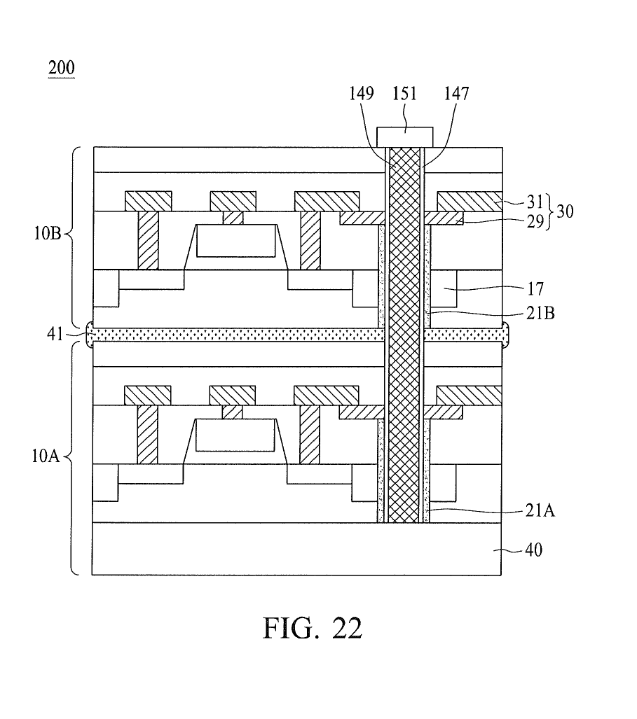

FIG. 21 and FIG. 22 are cross-sectional views showing an integrated circuit device 200 in accordance with one embodiment of the present invention. In one embodiment of the present invention, the fabrication processes shown in FIG. 1 to FIG. 16 are repeated, the carrier 39C and the adhesive 37C are removed from the top side of the stacking wafer 10B, and a photolithographic process is then performed to form a mask layer 143 on the stacking wafer 10B. Subsequently, a dry etching process using fluorine-containing etching gas is performed by using the backside dielectric layer 40 as an etching stop layer to form at least one via hole 145 penetrating through the stacking wafer 10B and into the bottom wafer 10A in a substantially linear manner. In one embodiment of the present invention, the at least one via hole 45 is formed within the annular dielectric block 21A and the annular dielectric block 21B. The via hole 45 shown in FIG. 17 does not expose the inner sidewall 22A of the annular dielectric block 21A; in contrast, the via hole 145 shown in FIG. 21 exposes the inner sidewall 22A of the annular dielectric block 21A, i.e., the size of the via hole 145 shown in FIG. 21 is larger than that of the via hole 45 shown in FIG. 17.

Referring to FIG. 22, the fabrication processes shown in FIG. 18 to FIG. 20 are repeated to form a barrier layer and seed layer 147 in the via hole 145, a conductive via (TSV) 149 in the via hole 145, and a bump pad 151 on the stacking wafer 10B to complete the integrated circuit device 200, and the carrier 39B and the adhesive 37B are removed from the back side of the bottom wafer 10A.

Compared to the technique disclosed in U.S. Pat. No. 7,683,459 forming one bump pad for each wafer, the embodiment of the present invention forms the integrated circuit device 100 by bonding wafers 10A and 10B before the formation of the through silicon via 47 that penetrates through the stacking wafer 10B and not through the backside dielectric layer 40 of the bottom wafer 10A. Consequently, the embodiment of the present invention does not need to form the bump pad 49 between the stacking wafer 10B and the bottom wafer 10A; therefore, the issues of complicated processing and high cost can be solved.

In addition, the conductive via 47 is formed within the annular dielectric block 21A and the annular dielectric block 21B, such that the annular dielectric block 21B electrically isolates the conductive via 47 from other elements in the stacking wafer 10B and the annular dielectric block 21A electrically isolates the conductive via 47 from other elements in the bottom wafer 10A.

Although the present invention and its advantages have been described in detail, it should be understood that various changes, substitutions and alterations can be made hereto without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An integrated circuit device, comprising:
a bottom wafer having a first annular dielectric block;
at least one stacking wafer having a second annular dielectric block positioned on the bottom wafer, wherein the bottom wafer and the stacking wafer are bonded by an intervening adhesive layer, and no bump pad is positioned between the bottom wafer and the stacking wafer; and
a conductive via penetrating through the stacking wafer and into the bottom wafer in a substantially linear manner, wherein the conductive via is to positioned within the first annular dielectric block and the second annular dielectric block.

2. The integrated circuit device of claim 1, wherein the first annular dielectric block comprises an inner sidewall, and the conductive via contacts the inner sidewall.

3. The integrated circuit device of claim 1, wherein the first annular dielectric block comprises an inner sidewall, and the conductive via is separated from the inner sidewall.

4. The integrated circuit device of claim 1, wherein the bottom wafer includes a backside dielectric layer, and the conductive via does not penetrate through the backside dielectric layer of the bottom wafer.

5. The integrated circuit device of claim 1, wherein the at least one stacking wafer comprises a top wafer having a bump pad, and the conductive via is connected to the bump pad.

6. The integrated circuit device of claim 1, wherein the stacking wafer comprises a contact plug and an interconnect, and the interconnect and the contact plug are made of the same conductive material.

7. The integrated circuit device of claim 1, wherein the stacking wafer comprises an active element and a trench isolation next to the active element, and the conductive via is positioned in the trench isolation.

8. The integrated circuit device of claim 1, wherein no solder is positioned between the bottom wafer and the stacking wafer.

9. A method for preparing an integrated circuit device, comprising the steps of:
forming a bottom wafer having a first annular dielectric block;
forming at least one stacking wafer having a second annular dielectric block;
bonding the at least one stacking wafer to the bottom wafer by an intervening adhesive layer, without forming a bump pad between the bottom wafer and the stacking wafer; and
forming a conductive via penetrating through the stacking wafer and into the bottom wafer in a substantially linear manner, wherein the conductive via is formed within the first annular dielectric block and the second annular dielectric block.

10. The method for preparing an integrated circuit device of claim 9, wherein the forming of the stacking wafer having a first annular dielectric block comprises the steps of:
forming an annular depression in the stacking wafer; and
filling the annular depression with dielectric material.

11. The method for preparing an integrated circuit device of claim 10, wherein the annular depression is formed in a shallow trench isolation of the stacking wafer.

12. The method for preparing an integrated circuit device of claim 9, wherein the forming of the conductive via comprises a step of forming a via hole within the first annular dielectric block, and the via hole exposes the inner sidewall of the first annular dielectric block.

13. The method for preparing an integrated circuit device of claim 9, wherein the forming of the conductive via comprises a step of forming a via hole within the first annular dielectric block, and the via hole is separated from the inner sidewall of the first annular dielectric block.

14. The method for preparing an integrated circuit device of claim 9, wherein the conductive via is formed without penetrating through the bottom wafer.

15. The method for preparing an integrated circuit device of claim 9, further comprising a step of forming a bump pad on the stacking wafer, to wherein the conductive via is connected to the bump pad.

16. The method for preparing an integrated circuit device of claim 9, wherein the forming of the stacking wafer comprises a step of forming a contact plug and an interconnect, and the interconnect and the contact plug are made of the same conductive material.

17. The method for preparing an integrated circuit device of claim 9, wherein the forming of the stacking wafer comprises a step of forming a trench isolation in a predetermined area of the stacking wafer, and the conductive via is positioned in the trench isolation.

18. The method for preparing an integrated circuit device of claim 9, wherein the bonding of the at least one stacking wafer to the bottom wafer is performed without using solder between the bottom wafer and the stacking wafer.

19. The method for preparing an integrated circuit device of claim 9, wherein the forming of the bottom wafer comprises a step of forming a backside dielectric layer on the bottom side of the bottom wafer.

20. The method for preparing an integrated circuit device of claim 19, wherein the forming of the conductive via comprises a step of forming a via hole within the first annular dielectric block, and the backside dielectric layer is used as an etching stop layer for forming the via hole.
